(19) United States
(12) Patent Application Publication
(10) Pub. No.: US 2025/0096047 A1
(43) Pub. Date: Mar. 20, 2025

(54) SEMICONDUCTOR PACKAGE AND METHOD OF TESTING THE SAME

(71) Applicant: SAMSUNG ELECTRONICS CO., LTD., SUWON-SI (KR)

(72) Inventors: YEONGSEON KIM, SUWON-SI (KR); DONGKUK LEE, SUWON-SI (KR); CHAJEA JO, SUWON-SI (KR)

(21) Appl. No.: 18/624,214

(22) Filed: Apr. 2, 2024

(30) Foreign Application Priority Data
Sep. 18, 2023 (KR) 10-2023-0124051

(51) Int. Cl. H01L 21/66; G01R 31/28; H01L 23/00; H01L 25/065

(52) U.S. Cl. CPC H01L 22/32; G01R 31/2884; H01L 22/14; H01L 24/08; H01L 24/16; H01L 25/0657; H01L 2224/08145; H01L 2224/16225; H01L 2225/06541; H01L 2924/30101

(57) ABSTRACT

A semiconductor package includes a substrate. A first semiconductor chip is on the substrate and includes a first semiconductor substrate and a plurality of first test pads on a top surface of the first semiconductor substrate. A second semiconductor chip is on the first semiconductor chip and includes a second semiconductor substrate and a second test pad on a bottom surface of the second semiconductor substrate. The first semiconductor chip and the second semiconductor chip are bonded to each other. The plurality of first test pads face the second test pad. The second test pad has a circular ring shape when viewed in plan. The plurality of first test pads are arranged along a circumference of the second test pad. Areas that the plurality of first test pads overlap the second test pad have same sizes as each other.

### CROSS-REFERENCE TO RELATED APPLICATION

This application claims priority under 35 U.S.C § 119 to Korean Patent Application No. 10-2023-0124051, filed on Sep. 18, 2023 in the Korean Intellectual Property Office, the disclosure of which is incorporated by reference in its entirety herein.

### 1. TECHNICAL FIELD

Embodiments of the present inventive concept relate to a semiconductor package and a method of testing the same.

### 2. DISCUSSION OF RELATED ART

In the semiconductor industry, integrated circuit packaging technology has been developed to be applied to small-form-factor devices and to provide high package reliability. For instance, package techniques capable of achieving a chip-sized package are actively being developed to provide small-form-factor devices. Additionally, package techniques capable of increasing efficiency in a package process and increasing mechanical and electrical reliability of a package product have attracted considerable attention.

In the semiconductor industry, there has been an increased demand for semiconductor devices and electronic products having a high capacity, thinness, and small size. One package technique that has been suggested is a packaging technique which vertically stacks a plurality of semiconductor chips to achieve a high density chip stacking. This packaging technique has an advantage of integrating semiconductor chips having various functions on a relatively small area as compared to a conventional package consisting of one semiconductor chip.

As a semiconductor process becomes finer and more complicated, it is essential to test defects produced on a semiconductor device. The test of defects on the semiconductor package increases the reliability of the semiconductor package and increases a process yield.

### SUMMARY

Some embodiments of the present inventive concept provide a semiconductor package having a sufficient joint.

Some embodiments of the present inventive concept provide a method of testing a semiconductor package that causes no damage to the semiconductor package and has a high accuracy.

According to an embodiment of the present inventive concept, a semiconductor package includes a substrate. A first semiconductor chip is on the substrate and includes a first semiconductor substrate and a plurality of first test pads on a top surface of the first semiconductor substrate. A second semiconductor chip is on the first semiconductor chip and includes a second semiconductor substrate and a second test pad on a bottom surface of the second semiconductor substrate. The first semiconductor chip and the second semiconductor chip are bonded to each other. The plurality of first test pads face the second test pad. The second test pad has a circular ring shape when viewed in plan. The plurality of first test pads are arranged along a circumference of the second test pad. Areas that the plurality of first test pads overlap the second test pad have same sizes as each other.

According to an embodiment of the present inventive concept, a semiconductor package includes a substrate. A first semiconductor chip is on the substrate. A second semiconductor chip is on the first semiconductor chip. The first semiconductor chip includes a first semiconductor substrate. A first circuit layer is on a bottom surface of the first semiconductor substrate. A plurality of first test pads is on a top surface of the first semiconductor substrate. A plurality of external pads is on the bottom surface of the first semiconductor substrate. A plurality of through vias vertically penetrates the first semiconductor substrate to connect the plurality of first test pads to the external pads. The second semiconductor chip includes a second semiconductor substrate. A second circuit layer is on a bottom surface of the second semiconductor substrate. A second test pad is on the bottom surface of the second semiconductor substrate. Each of the plurality of first test pads partially overlaps the second test pad. The plurality of first test pads are arranged at a same interval. The plurality of first test pads and the second test pad are electrically insulated from the first circuit layer and the second circuit layer. Each of the external pads is electrically connected through the through via to one of the plurality of first test pads.

According to an embodiment of the present inventive concept, a method of testing a semiconductor package includes forming a wiring pattern in a first semiconductor substrate and a plurality of first test pads on a top surface of the first semiconductor substrate. The plurality of first test pads are electrically connected to the wiring pattern. Each of the plurality of first test pads has a circular shape when viewed in plan. A second test pattern is formed on a bottom surface of the second semiconductor substrate. The second test pad has a circular ring shape when viewed in plan. The first semiconductor substrate and the second semiconductor substrate are bonded to each other. The plurality of first test pads face the second pad after the bonding to each other. The plurality of first test pads are arranged along a circumference of the second test pad. Each of the plurality of first test pads partially overlaps the second test pad. A plurality of external pads is formed on a bottom surface of the first semiconductor substrate. Each of the external pads are electrically connected through the wiring pattern to one of the plurality of first test pads. Two of the external pads are used to measure an electrical resistance of a test path. The electrical resistance of the test path is compared with a reference resistance.

### BRIEF DESCRIPTION OF DRAWINGS

FIG. 1 illustrates a cross-sectional view showing a semiconductor package according to an embodiment of the present inventive concept.

FIG. 2 illustrates an enlarged view showing a portion of FIG. 1 according to an embodiment of the present inventive concept.

FIG. 3 illustrates a perspective view showing a test structure according to an embodiment of the present inventive concept.

FIGS. 4 to 9 illustrate plan views showing a test structure according to embodiments of the present inventive concept.

FIG. 10 illustrates a cross-sectional view showing a semiconductor package according to an embodiment of the present inventive concept.

FIG. 11 illustrates a cross-sectional view showing a semiconductor module according to an embodiment of the present inventive concept.

FIGS. 12A to 16A illustrate cross-sectional views showing a method of fabricating and testing a semiconductor package according to some embodiments of the present inventive concept.

FIGS. 12B, 13B, 14B, 15B, 15C, 15D, 16B, and 16C illustrate plan views showing a test structure in a method of fabricating and testing a semiconductor package according to some embodiments of the present inventive concept.

### DETAILED DESCRIPTION OF EMBODIMENTS

The following will now describe a semiconductor package according to the present inventive concept with reference to the accompanying drawings.

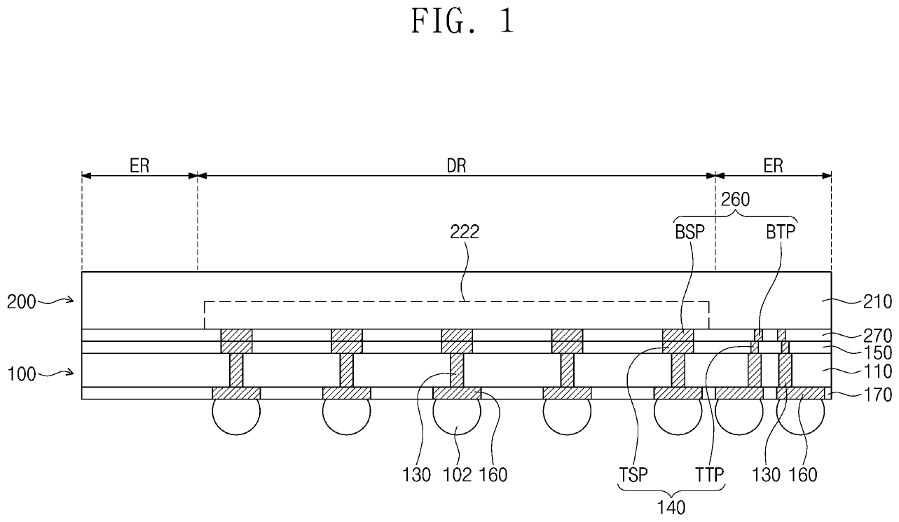

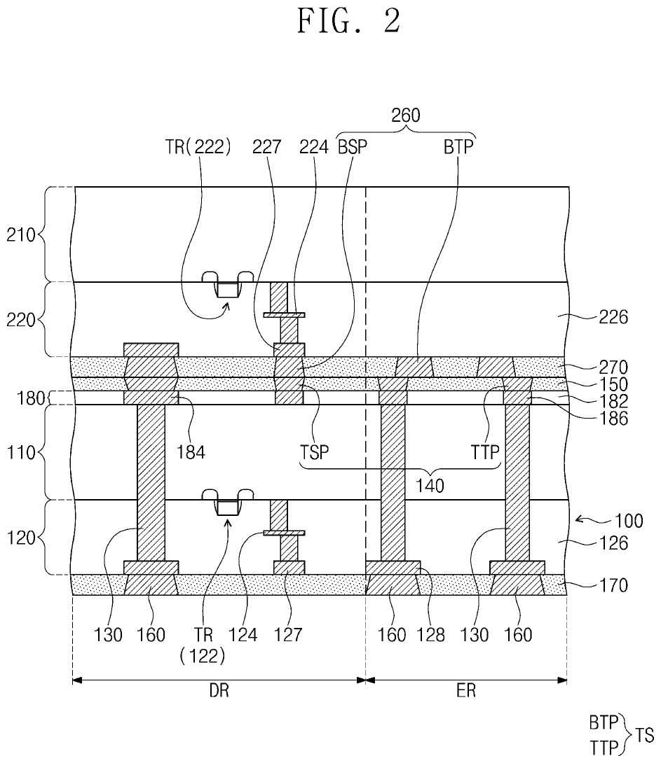

FIG. 1 illustrates a cross-sectional view showing a semiconductor package according to some embodiments of the present inventive concept. For convenience of description, some components may be omitted or components may be merged into a single configuration in FIG. 1. FIG. 2 illustrates an enlarged view showing a portion of FIG. 1.

A semiconductor package according to some embodiments of the present inventive concept may be a stacked package in which vias are used. For example, semiconductor chips of the same type may be stacked on a base substrate, and the semiconductor chips may be electrically connected to each other through vias that penetrate therethrough. The semiconductor chips may be bonded to each other through respective pads that face each other.

Referring to FIGS. 1 and 2, a semiconductor package may include a first semiconductor chip 100 and a second semiconductor chip 200 that are stacked on each other.

The first semiconductor chip 100 may be provided. The first semiconductor chip 100 may include an integrated circuit therein. For example, in an embodiment the first semiconductor chip 100 may be a wafer-level die formed of a semiconductor, such as silicon (Si). In an embodiment, the first semiconductor chip 100 may include a first semiconductor substrate 110, a first circuit layer 120, first vias 130, first upper pads 140, a first upper protection layer 150, first lower pads 160, a first lower protection layer 170, and a redistribution layer 180.

The first semiconductor substrate 110 may be provided. The first semiconductor substrate 110 may include a semiconductor material. For example, in an embodiment the first semiconductor substrate 110 may be a silicon (Si) monocrystalline substrate.

The first semiconductor substrate 110 may have a device region DR and an edge region ER that are spaced apart from each other. In an embodiment, when viewed in plan, the device region DR may be positioned on a central portion of the first semiconductor substrate 110, and the edge region ER may surround the device region DR. The device region DR may be a region on which semiconductor devices of the first semiconductor chip 100 is provided on the central portion of the first semiconductor substrate 110. The edge region ER may be a test region on which patterns are provided for testing a joint between the semiconductor chips 100 and 200 on a zone where the semiconductor devices are not provided on the first semiconductor substrate 110. The first semiconductor substrate 110 may have a top surface and a bottom surface that are opposite to each other. The bottom surface of the first semiconductor substrate 110 may be a front surface of the first semiconductor substrate 110, and the top surface of the first semiconductor substrate 110 may be a rear surface of the first semiconductor substrate 110. In this description, the front surface of the first semiconductor substrate 110 may be defined to indicate a surface on which semiconductor devices are formed or mounted in the first semiconductor substrate 110 or on which wiring lines and pads are formed in the first semiconductor substrate 110, and the rear surface of the first semiconductor substrate 110 may be defined to indicate a surface opposite to the front surface. For example, the bottom surface of the first semiconductor substrate 110 may be an active surface.

The first semiconductor chip 100 may have the first circuit layer 120 provided on the bottom surface of the first semiconductor substrate 110. The first circuit layer 120 may include a first semiconductor device 122 and a first device wiring part 124.

On the device region DR of the first semiconductor substrate 110, the first semiconductor device 122 may include transistors TR provided on the bottom surface of the first semiconductor substrate 110. For example, the transistors TR may each include a source and a drain that are formed on a lower portion of the first semiconductor substrate 110, a gate electrode disposed on the bottom surface of the first semiconductor substrate 110, and a gate dielectric layer interposed between the first semiconductor substrate 110 and the gate electrode. FIG. 2 depicts that one transistor TR is provided. However, embodiments of the present inventive concept are not necessarily limited thereto. The first semiconductor device 122 may include a plurality of transistors TR. In an embodiment, the first semiconductor device 122 may include a logic circuit or a memory circuit. In an embodiment, on the device region DR, the first semiconductor device 122 may include a device isolation pattern, a logic cell or a plurality of memory cells on the bottom surface of the first semiconductor substrate 110. Alternatively, in an embodiment the first semiconductor device 122 may include a passive device, such as a capacitor. The first semiconductor device 122 may not be disposed on the edge region ER of the first semiconductor substrate 110.

The bottom surface of the first semiconductor substrate 110 may be covered with a first device interlayer dielectric layer 126. On the device region DR, the first device interlayer dielectric layer 126 may bury the first semiconductor device 122. The first device interlayer dielectric layer 126 may downwardly cover the first semiconductor device 122. For example, the first semiconductor device 122 may not be exposed by the first device interlayer dielectric layer 126. In an embodiment, the first device interlayer dielectric layer 126 may include, for example, at least one selected from silicon oxide (SiO), silicon nitride (SiN), and silicon oxynitride (SiON). Alternatively, the first device interlayer dielectric layer 126 may have a low-k dielectric material. The first device interlayer dielectric layer 126 may have a mono-layered structure or a multi-layered structure. In an embodiment in which the first device interlayer dielectric layer 126 is provided as the multi-layered structure, subsequently described wiring layers may be provided in each dielectric layer, and an etch stop layer may be interposed between the dielectric layers. For example, the etch stop layer may be provided on a bottom surface of each dielectric layer. In an embodiment, the etch stop layer may include, for example, one of silicon nitride (SiN), silicon oxynitride (SiON), and silicon carbonitride (SiCN).

On the device region DR, the first device interlayer dielectric layer 126 may be provided therein with the first device wiring part 124 connected to the transistors TR. The first device wiring part 124 may include signal wiring patterns buried in the first device interlayer dielectric layer 126. For example, in an embodiment the signal wiring patterns may include redistribution patterns for horizontal wiring and via patterns for vertical connection. The first device wiring part 124 may vertically penetrate the first device interlayer dielectric layer 126 to come into connection with (e.g., electrical connection therewith) one of a source electrode, a drain electrode, and a gate electrode of the transistor TR. Alternatively, the first device wiring part 124 may be connected to various components of the first semiconductor device 122. The first device wiring part 124 may be positioned between top and bottom surfaces of the first device interlayer dielectric layer 126. The first device wiring part 124 may not be positioned on the edge region ER. In an embodiment, the first device wiring part 124 may include, for example, copper (Cu) or tungsten (W).

FIG. 2 depicts that one wiring layer is provided in the first device interlayer dielectric layer 126. However, embodiments of the present inventive concept are not necessarily limited thereto. According to some embodiments, a plurality of wiring layers may be provided in the first device interlayer dielectric layer 126. The following description will focus on the embodiment of FIG. 2 for convenience of explanation.

First and second lower connection patterns 127 and 128 may be provided in a lower portion of the first device interlayer dielectric layer 126. In an embodiment, the first and second lower connection patterns 127 and 128 may have bottom surfaces that are exposed on the bottom surface of the first device interlayer dielectric layer 126. In an embodiment, the bottom surfaces of the first and second lower connection patterns 127 and 128 may be coplanar with the bottom surface of the first device interlayer dielectric layer 126. The first lower connection patterns 127 may be disposed on the device region DR. One of the first lower connection patterns 127 may be connected to (e.g., electrically connected thereto) the first device wiring part 124. The second lower connection patterns 128 may be disposed on the edge region ER. The second lower connection patterns 128 may be electrically insulated from the first semiconductor device 122 and the first device wiring part 124. In an embodiment, the first and second lower connection patterns 127 and 128 may include, for example, copper (Cu) or tungsten (W).

The first vias 130 may be arranged to vertically penetrate the first semiconductor substrate 110 to come into connection with the first lower connection patterns 127. The first vias 130 may be patterns for vertical wiring. On the device region DR, one of the first vias 130 may vertically penetrate the first device interlayer dielectric layer 126 on the device region DR to be coupled to a top surface of one of the first lower connection patterns 127. On the edge region ER, another of the first vias 130 may vertically penetrate the first device interlayer dielectric layer 126 to be coupled to a top surface of one of the second lower connection patterns 128. The first vias 130 may vertically penetrate the first device interlayer dielectric layer 126 and the first semiconductor substrate 110 to be exposed on the top surface of the first semiconductor substrate 110. In an embodiment, the first vias 130 may include, for example, tungsten (W).

The first lower pads 160 may be disposed on the first device interlayer dielectric layer 126. The first lower pads 160 may be disposed on the bottom surfaces of the first and second lower connection patterns 127 and 128 and may directly contact the first and second lower connection patterns 127, 128. The first lower pads 160 may be disposed on a bottom surface of the first semiconductor substrate 110. The first lower pads 160 may be coupled to the bottom surfaces of the first and second lower connection patterns 127 and 128 of the first device wiring part 124. For example, the first and second lower connection patterns 127 and 128 may be under pads of the first lower pads 160. In an embodiment, the first lower pads 160 may have plate shapes. According to some embodiments, the first lower pads 160 may each have a T-shaped cross-section including a via portion and a pad portion on the via portion in which via and pad portions are connected into a single unitary piece. The first lower pads 160 may include a metallic material. For example, in an embodiment the first lower pads 160 may include copper (Cu).

The first lower protection layer 170 may be disposed on (e.g., disposed directly thereon) the first device interlayer dielectric layer 126. On the bottom surface of the first device interlayer dielectric layer 126, the first lower protection layer 170 may cover the first and second lower connection patterns 127 and 128. On the bottom surface of the first device interlayer dielectric layer 126, the first lower protection layer 170 may surround the first lower pads 160, such as lateral side surfaces of the first lower pads 160. The first lower pads 160, such as an upper surface of the first lower pads 160, may be exposed by the first lower protection layer 170. For example, when viewed in plan, the first lower protection layer 170 may surround, but not directly contact, upper surfaces of the first lower pads 160. The first lower protection layer 170 may have a bottom surface coplanar with those of the first lower pads 160. In an embodiment, the first lower protection layer 170 may include one of silicon nitride (SiN), silicon oxide (SiO), silicon carboxide (SiOC), silicon oxynitride (SiON), and silicon carbonitride (SiCN).

The first lower pads 160 may be external pads for outwardly mounting the semiconductor package. For example, in an embodiment external terminals 102 may be provided on the first lower pads 160. The external terminals 102 may be coupled to the first lower pads 104. In some embodiments, the external terminals 102 may include a solder ball or a solder bump, and based on type and arrangement of the external terminals 102, the semiconductor package may be provided in the shape of one of a ball grid array (BGA) type, a fine ball-grid array (FBGA) type, and a land grid array (LGA) type.

The redistribution layer 180 may be disposed on (e.g., disposed directly thereon) the top surface of the first semiconductor substrate 110. In an embodiment, the redistribution layer 180 may include first and second upper connection patterns 184 and 186 and a first redistribution dielectric pattern 182.

The first redistribution dielectric pattern 182 may be disposed on (e.g., disposed directly thereon) the top surface of the first semiconductor substrate 110. In an embodiment, the first redistribution dielectric pattern 182 may include one of silicon nitride (SiN), silicon oxide (SiO), and silicon oxynitride (SiON).

On the device region DR, the first upper connection patterns 184 may be disposed in the first redistribution dielectric pattern 182. Some of the first upper connection patterns 184 may be connected to the first vias 130. For example, some of the first vias 130 may vertically penetrate the first semiconductor substrate 110 to be coupled to (e.g., directly coupled thereto) bottom surfaces of the first upper connection patterns 184. The first upper connection patterns 184 may not be positioned on the edge region ER. In an embodiment, the first upper connection patterns 184 may include, for example, copper (Cu) or tungsten (W).

On the edge region ER, the second upper connection patterns 186 may be provided in the first redistribution dielectric pattern 182. The second upper connection patterns 186 may be located at the same level as that of the first upper connection patterns 184, and may include the same material as that of the first upper connection patterns 184. For example, in an embodiment the first and second upper connection patterns 184 and 186 may be patterned by patterning a metal layer. The second upper connection patterns 186 may be electrically insulated from the first semiconductor device 122 and the first device wiring part 124. In addition, the second upper connection patterns 186 may be electrically insulated from other devices and wiring lines provided in the semiconductor package. Each of the second upper connection patterns 186 may be connected through the first via 130 to one of the second lower connection patterns 128. For example, the second upper connection patterns 186 and the second lower connection patterns 128 may be electrically floated in the semiconductor package. The second upper connection patterns 186 may not be disposed on the device region DR of the first semiconductor substrate 110. In an embodiment, the second upper connection patterns 186 may include, for example, copper (Cu) or tungsten (W).

The first and second upper connection patterns 184 and 186 may have top surfaces that are exposed on a top surface of the first redistribution dielectric pattern 182. For example, the top surfaces of the first and second upper connection patterns 184 and 186 may be coplanar with the top surface of the first redistribution dielectric pattern 182. In an embodiment, the top surfaces of the first and second upper connection patterns 184 and 186 may be substantially flat, and likewise the top surface of the first redistribution dielectric pattern 182 may be substantially flat.

The first upper pads 140 may be disposed on (e.g., disposed directly thereon) the redistribution layer 180. In an embodiment, the first upper pads 140 may include upper signal pads TSP and upper test pads TTP disposed on a top surface of the first semiconductor substrate 110.

The upper signal pads TSP may be disposed on the device region DR. The upper signal pads TSP may be disposed on (e.g., disposed directly thereon) top surfaces of the first upper connection patterns 184. The first upper connection patterns 184 may be under pads of the upper signal pads TSP. The first upper connection patterns 184 may electrically connect the first semiconductor device 122 to the upper signal pads TSP.

The upper test pads TTP may be disposed on the edge region ER. The upper test pads TTP may be disposed on (e.g., disposed directly thereon) top surfaces of the second upper connection patterns 186. The second upper connection patterns 186 may be under pads of the upper test pads TTP. The following will describe in detail a shape and arrangement of the upper test pads TTP together with a lower test pad BTP of the second semiconductor chip 200 which will be discussed below. The upper test pads TTP may be electrically insulated from the first semiconductor device 122 and the first device wiring part 124. When viewed in cross section, an interval between the upper test pads TTP may be less than that between the upper signal pads TSP. For example, the distance between adjacent upper test pads TTP may be less than the distance between adjacent upper signal pads TSP.

In an embodiment, the first upper pads 140 may have plate shapes. The first upper pads 140 may each have a width that decreases as the distance from the first semiconductor substrate 110 decreases. According to an embodiment, the first upper pads 140 may each have a T shaped cross-section including a via portion and a pad portion on the via portion. In an embodiment, the via and pad portions are connected into a single unitary piece. The first upper pads 140 may include a metallic material. For example, in an embodiment the first upper pads 140 may include copper (Cu).

The first upper protection layer 150 may be disposed on (e.g., disposed directly thereon) the redistribution layer 180. On a top surface of the redistribution layer 180, the first upper protection layer 150 may cover the first and second upper connection patterns 184 and 186. On the top surface of the redistribution layer 180, the first upper protection layer 150 may surround the first upper pads 140, such as lateral side surfaces of the first upper pads 140. The first upper pads 140, such as upper surfaces of the first upper pads 140, may be exposed by the first upper protection layer 150. For example, when viewed in plan, the first upper protection layer 150 may surround, but not directly contact, upper surfaces of the first upper pads 140. The first upper protection layer 150 may have a top surface coplanar with top surfaces of the first upper pads 140. In an embodiment, the first upper protection layer 150 may include one of high density plasma (HDP) oxide, undoped silicate glass (USG), tetraethyl orthosilicate (TEOS), silicon nitride (SiN), silicon oxide (SiO), silicon carboxide (SiOC), silicon oxynitride (SiON), and silicon carbonitride (SiCN). The first upper protection layer 150 may have a mono-layered structure or a multi-layered structure.

The second semiconductor chip 200 may have a structure substantially similar to that of the first semiconductor chip 100. For example, the second semiconductor chip 200 may include a second semiconductor substrate 210, a second circuit layer 220, second lower pads 260, and a second lower protection layer 270. In an embodiment, the second semiconductor chip 200 may not include a second via, a second upper pad, a second upper protection layer, and a second redistribution layer. However, embodiments of the present inventive concept are not necessarily limited thereto. According to some embodiments, the second semiconductor chip 200 may include at least one selected from a second via, a second upper protection layer, and a redistribution layer.

The second semiconductor substrate 210 may be provided. The second semiconductor substrate 210 may include a semiconductor material.

The second circuit layer 220 may be provided on (e.g., disposed directly on) a bottom surface of the second semiconductor substrate 210. The second circuit layer 220 may include a second semiconductor device 222 and a second device wiring part 224. In an embodiment, on the device region DR of the second semiconductor substrate 210, the second semiconductor device 222 may include transistors TR provided on the bottom surface of the second semiconductor substrate 210. The second semiconductor device 222 may not be disposed on the edge region ER of the second semiconductor substrate 210. The bottom surface of the second semiconductor substrate 210 may be covered with a second device interlayer dielectric layer 226. On the device region DR, the second device interlayer dielectric layer 226 may bury the second semiconductor device 222. On the device region DR, the second device interlayer dielectric layer 226 may be provided therein with the second device wiring part 224 connected to the transistors TR.

Third lower connection patterns 227 may be provided in a lower portion of the second device interlayer dielectric layer 226. The third lower connection patterns 227 may have bottom surfaces that are exposed on a bottom surface of the second device interlayer dielectric layer 226. The third lower connection patterns 227 may be disposed on the device region DR. The third lower connection patterns 227 may be connected to the second device wiring part 224.

The second lower pads 260 may be disposed on (e.g., disposed directly thereon) the second device interlayer dielectric layer 226. In an embodiment, the second lower pads 260 may include lower signal pads BSP and a lower test pad BTP.

The lower signal pads BSP may be disposed on the device region DR. The lower signal pads BSP may be disposed on (e.g., disposed directly thereon) the bottom surfaces of the third lower connection patterns 227. The lower signal pads BSP may be electrically connected to the second semiconductor device 222. For example, as shown in FIG. 2, on the device region DR, the lower signal pads BSP may be coupled to (e.g., directly coupled thereto) the bottom surfaces of the third lower connection patterns 227 included in the second device wiring part 224. For example, the third lower connection patterns 227 may be under pads of the lower signal pads BSP. The third lower connection patterns 227 may electrically connect the second semiconductor device 222 to the lower signal pads BSP.

The lower test pad BTP may be disposed on the edge region ER. The lower test pad BTP may be located at the same level as that of the lower signal pads BSP. The following will describe in detail a shape and arrangement of the lower test pad BTP together with the upper test pads TTP of the first semiconductor chip 100. The lower test pad BTP may be electrically insulated from the second semiconductor device 222 and the second device wiring part 224.

The second lower protection layer 270 may be disposed on (e.g., disposed directly thereon) the second device interlayer dielectric layer 226. On the bottom surface of the second device interlayer dielectric layer 226, the second lower protection layer 270 may cover the third lower connection patterns 227. On the bottom surface of the second device interlayer dielectric layer 226, the second lower protection layer 270 may surround the second lower pads 260. The second lower pads 260, such as upper surfaces of the second lower pads 260, may be exposed by the second lower protection layer 270. For example, when viewed in plan, the second lower protection layer 270 may surround, but not directly contact, upper surfaces of the second lower pads 260. The second lower protection layer 270 may have a bottom surface coplanar with those of the second lower pads 260. In an embodiment, the second lower protection layer 270 may include one of silicon nitride (SiN), silicon oxide (SiO), silicon carboxide (SiOC), silicon oxynitride (SiON), and silicon carbonitride (SiCN).

The second semiconductor chip 200 may be disposed on the first semiconductor chip 100. In an embodiment, the first upper pads 140 of the first semiconductor chip 100 may be vertically aligned with the second lower pads 260 of the second semiconductor chip 200. The first semiconductor chip 100 and the second semiconductor chip 200 may be in direct contact with each other.

On an interface between the first semiconductor chip 100 and the second semiconductor chip 200, the first upper protection layer 150 of the first semiconductor chip 100 may be bonded to the second lower protection layer 270 of the second semiconductor chip 200. In an embodiment, the first upper protection layer 150 and the second lower protection layer 270 may constitute a hybrid bonding of oxide, nitride, or oxynitride. In this description, the term “hybrid bonding” may denote a bonding in which two components of the same kind are merged at an interface therebetween. For example, the first upper protection layer 150 and the bonded second lower protection layer 270 may have a continuous configuration and there may be no visible interface therebetween. For example, the first upper protection layer 150 and the second lower protection layer 270 may be formed of the same material, and no interface may be present between the first upper protection layer 150 and the second lower protection layer 270. Thus, the first upper protection layer 150 and the second lower protection layer 270 may be provided as one integral component. For example, the first upper protection layer 150 and the second lower protection layer 270 may be combined to constitute a single unitary piece. The present inventive concept, however, are not necessarily limited thereto. For example, in an embodiment the first upper protection layer 150 and the second lower protection layer 270 may be formed of different materials. In this embodiment, the first upper protection layer 150 and the second lower protection layer 270 may not have a continuous, integral configuration and there may be a visible interface therebetween.

The first semiconductor chip 100 may be connected to the second semiconductor chip 200. For example, the first semiconductor chip 100 and the second semiconductor chip 200 may be in direct contact with each other. On the interface between the first semiconductor chip 100 and the second semiconductor chip 200, the first upper pads 140 of the first semiconductor chip 100 may be bonded to (e.g., directly bonded thereto) the second lower pads 260 of the second semiconductor chip 200. For example, the upper signal pads TSP of the first semiconductor chip 100 may be bonded to (e.g., directly bonded thereto) the lower signal pads BSP of the second semiconductor chip 200, and the upper test pads TTP of the first semiconductor chip 100 may be bonded to (e.g., directly bonded thereto) the lower test pads BTP of the second semiconductor chip 200. In this configuration, the first upper pad 140 and the second lower pad 260 may constitute an intermetallic hybrid bonding. For example, the first upper pad 140 and its bonded second lower pad 260 may have a continuous configuration and there may be no visible interface therebetween. For example, the first upper pads 140 and the second lower pads 260 may be formed of the same material and may have no interface therebetween. Therefore, the first upper pad 140 and the second lower pad 260 may be provided as one component. For example, the first upper pad 140 and the second lower pad 260 may be combined to constitute a single unitary piece.

As the first semiconductor chip 100 is bonded to the second semiconductor chip 200, on the edge region ER, the upper test pads TTP of the first semiconductor chip 100 may be electrically connected to the lower test pad BTP of the second semiconductor chip 200. In this embodiment, the upper test pads TTP of the first semiconductor chip 100 and the lower test pad BTP of the second semiconductor chip 200 may be combined to constitute a test structure TS. A configuration of the test structure TS will be discussed in detail below.

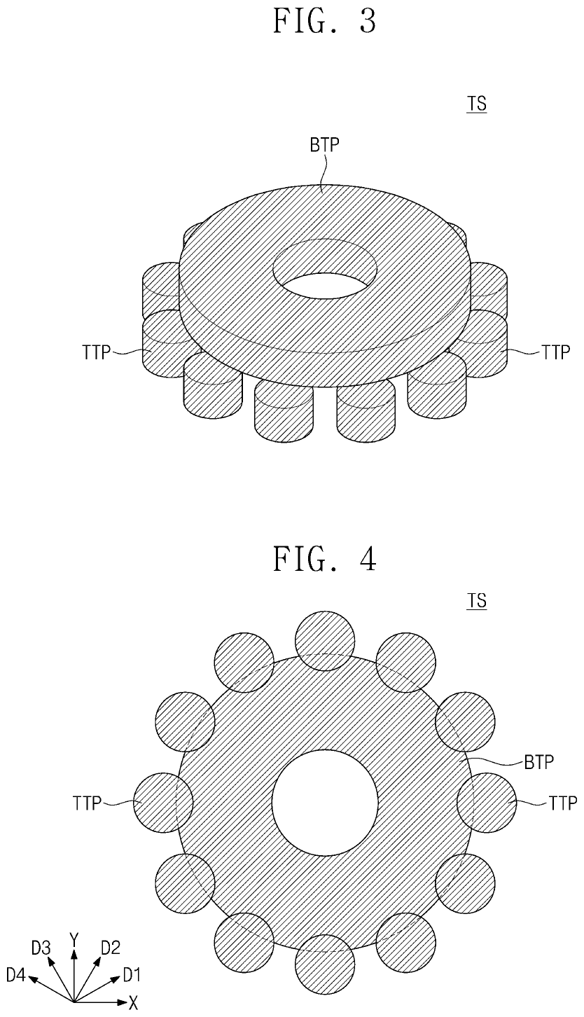

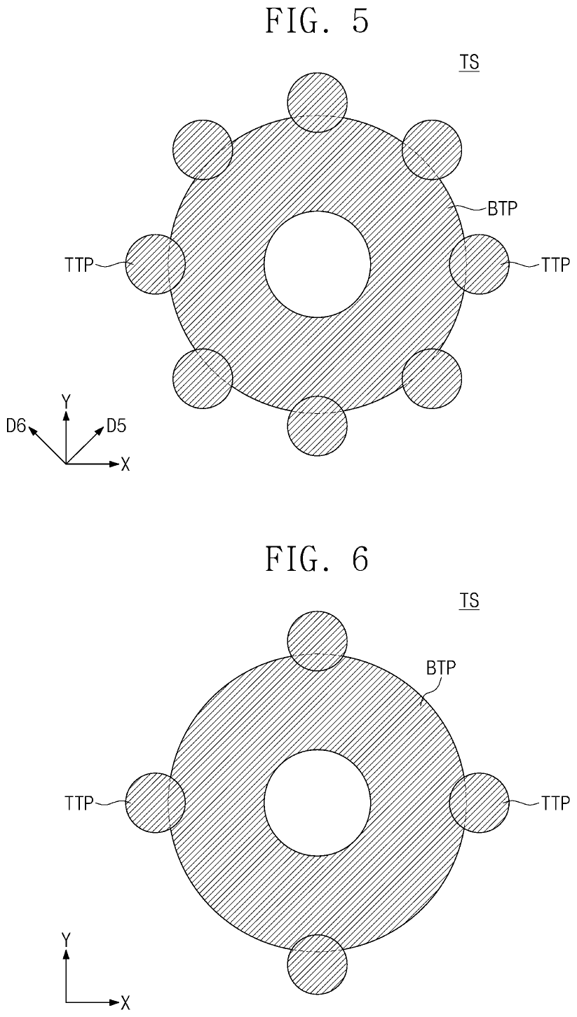

FIG. 3 illustrates a perspective view showing a test structure. FIGS. 4 to 6 illustrate plan views showing a test structure of FIG. 3 when viewed from above.

Referring to FIGS. 3 and 4, in an embodiment the lower test pad BTP may have a circular ring shape when viewed in plan. FIG. 3 depicts that the lower test pad BTP has a uniform width. However, embodiments of the present inventive concept are not necessarily limited thereto. According to some embodiments, the width of the lower test pad BTP may increase with decreasing distance from the upper test pads TTP. The width of the lower test pad BTP may indicate a distance from inner to outer lateral surfaces of the lower test pad BTP.

Each of the upper test pads TTP may have a circular shape when viewed in plan. For example, in an embodiment the upper test pads TTP may each have a cylindrical shape. FIG. 3 depicts that each of the upper test pads TTP has a uniform width. However, embodiments of the present inventive concept are not necessarily limited thereto. According to some embodiments, the width of each of the upper test pads TTP may increase with decreasing distance from the lower test pad BTP. In this description, the width of the upper test pad TTP may indicate a diameter of the upper test pad TTP. The upper test pads TTP may have their top surfaces whose shapes are the same as each other. For example, the top surfaces of the upper test pads TTP may have the same area size.

The upper test pads TTP may be arranged along a circumference of the lower test pad BTP. For example, the upper test pads TTP may be arranged in a circular shape. However, embodiments of the present disclosure are not necessarily limited thereto. For example, in an embodiment the upper test pads TTP may be arranged along the inner lateral surface of the lower test pad BTP. In an embodiment, there may be a regular interval between adjacent upper test pads TTP. In an embodiment, an interval between adjacent upper test pads TTP may be less than an interval between adjacent upper signal pads TSP. In an embodiment shown in FIG. 4, twelve upper test pads TTP may be provided. However, embodiments of the present disclosure are not necessarily limited thereto. Thus, the upper test pads TTP may be disposed on opposite sides in a first direction X of the lower test pad BTP, opposite sides in a second direction Y of the lower test pad BTP, and opposite sides of each of third, fourth, fifth, and sixth directions D1, D2, D3, and D4 of the lower test pad BTP. In this description, the first direction X and the second direction Y may be directions orthogonal to each other, and the third, fourth, fifth, and sixth directions D1, D2, D3, and D4 may be directions having an interval angle of about 60 degrees with respect to the first direction X and the second direction Y. A regular interval may be provided between the upper test pads TTP when viewed in cross section taken along the first to sixth directions X, Y, D1, D2, D3, and D4. For example, the same interval may be provided between the upper test pads TTP that stand opposite to each other in the first direction X, between the upper test pads TTP that stand opposite to each other in the second direction Y, between the upper test pads TTP that stand opposite to each other in the third direction D1, between the upper test pads TTP that stand opposite to each other in the fourth direction D2, between the upper test pads TTP that stand opposite to each other in the fifth direction D3, and between the upper test pads TTP that stand opposite to each other in the sixth direction D4.

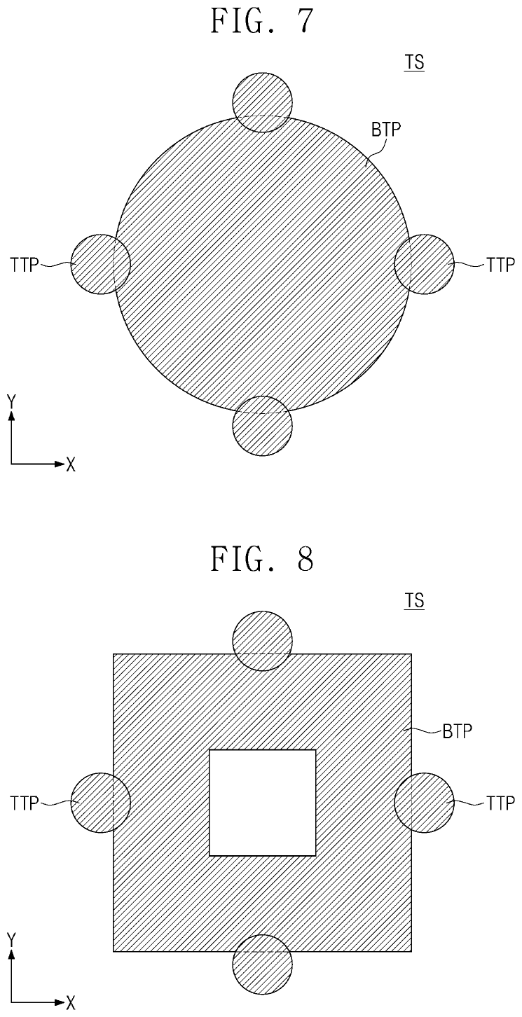

According to some embodiments, eight upper test pads TTP may be provided along the circumference of the lower test pad BTP. As illustrated in FIG. 5, the upper test pads TTP may be disposed on opposite sides in the first direction X of the lower test pad BTP, opposite sides in the second direction Y of the lower test pad BTP, and opposite sides of each of seventh and eighth directions D5 and D6 of the lower test pad BTP. In this description, the seventh and eighth directions D5 and D6 may be directions having an interval angle of about 45 degrees with respect to the first direction X and the second direction Y.

According to some embodiments, four upper test pads TTP may be provided along the circumference of the lower test pad BTP. As illustrated in FIG. 6, the upper test pads TTP may be disposed on opposite sides in the first direction X of the lower test pad BTP and opposite sides in the second direction Y of the lower test pad BTP.

FIGS. 4 to 6 depict that four, eight, or twelve upper test pads TTP are provided along the circumference of the lower test pad BTP. However, embodiments of the present inventive concept are not necessarily limited thereto. For example, in an embodiment, four to sixteen upper test pads TTP may be provided at a regular interval along the circumference of the lower test pad BTP. The following description will focus on the embodiment of FIG. 4.

Each of the upper test pads TTP may partially overlap the lower test pad BTP (e.g., in a vertical direction). In an embodiment, the same overlapping area size may be provided between the lower test pad BTP and each of the upper test pads TTP. Therefore, the same interfacial resistance may be present between the lower test pad BTP and each of the upper test pads TTP. In an embodiment, the overlapping area size between the lower test pad BTP and each of the upper test pads TTP may be in a range of about 10% to about 30% of an area size of each of the upper test pads TTP.

Each of the upper test pads TTP may be connected to the first lower pad 160 through a wiring pattern in the first semiconductor chip 100, or through the second upper connection pattern 186, the first via 130, and the second lower connection pattern 128. In an embodiment, as the upper test pads TTP are bonded to the lower test pad BTP, one of the first lower pads 160 may be electrically connected to the lower test pad BTP through one of the second lower connection patterns 128, one of the first vias 130, one of the second upper connection patterns 186, and one of the upper test pads TTP, and in addition may be electrically connected to another of the first lower pads 160 through the lower test pad BTP, another of the upper test pads TTP, another of the second upper connection patterns 186, another of the first vias 130, and another of the second lower connection patterns 128. In an embodiment, the first lower pads 160 electrically connected to the lower test pad BTP may be pads for inputting signals in a process where the bonding between the first and second semiconductor chips 100 and 200 is tested. This will be further discussed below in detail in describing a method of testing a semiconductor package.

In the embodiments that follow, a detailed description of technical features repetitive to those discussed above with reference to FIGS. 1 to 6 may be omitted, and a difference thereof will be discussed in detail for economy of description. The same reference numerals may be allocated to the same components as those of the semiconductor package discussed above according to some embodiments of the present inventive concept.

FIGS. 7 to 9 illustrate plan views showing a test structure.

FIGS. 4 to 6 depict that the lower test pad BTP has a circular ring shape when viewed in plan. However, embodiments of the present inventive concept are not necessarily limited thereto.

As illustrated in FIG. 7, the lower test pad BTP may have a circular shape when viewed in plan. For example, in an embodiment the lower test pad BTP may have a cylindrical shape. The upper test pads TTP may be arranged along a circumference of the lower test pad BTP. Each of the upper test pads TTP may partially overlap the lower test pad BTP (e.g., in a vertical direction).

Alternatively, as illustrated in FIG. 8, in an embodiment the lower test pad BTP may have a tetragonal ring shape when viewed in plan. In this embodiment, four upper test pads TTP may be provided along the circumference of the tetragonal ring shape of the lower test pad BTP. Each of the upper test pads TTP may be disposed adjacent to one of outer lateral surfaces of the lower test pad BTP. Each of the upper test pads TTP may partially overlap the lower test pad BTP (e.g., in a vertical direction).

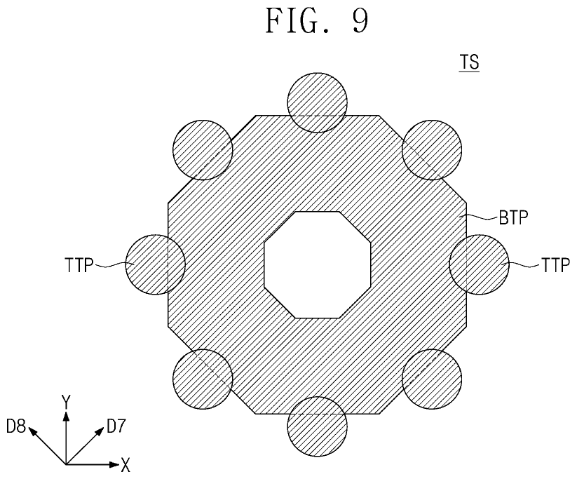

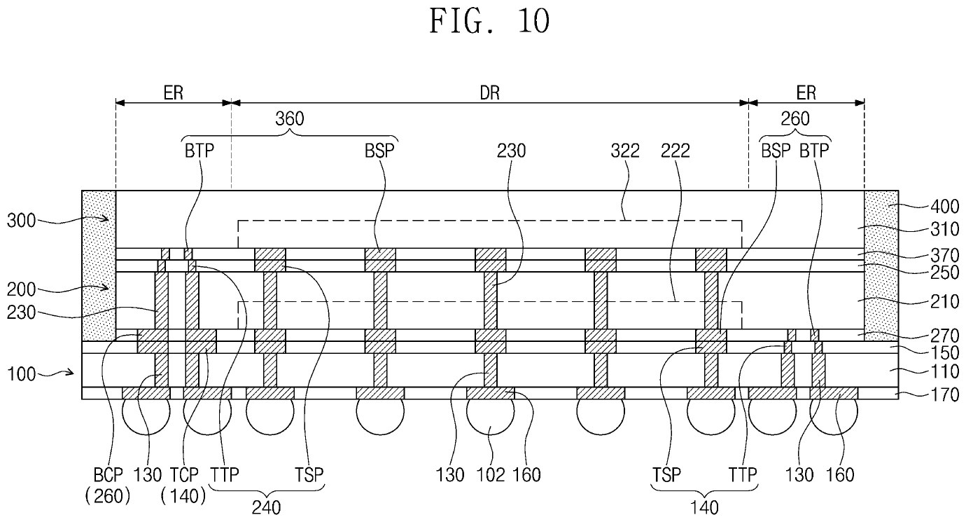

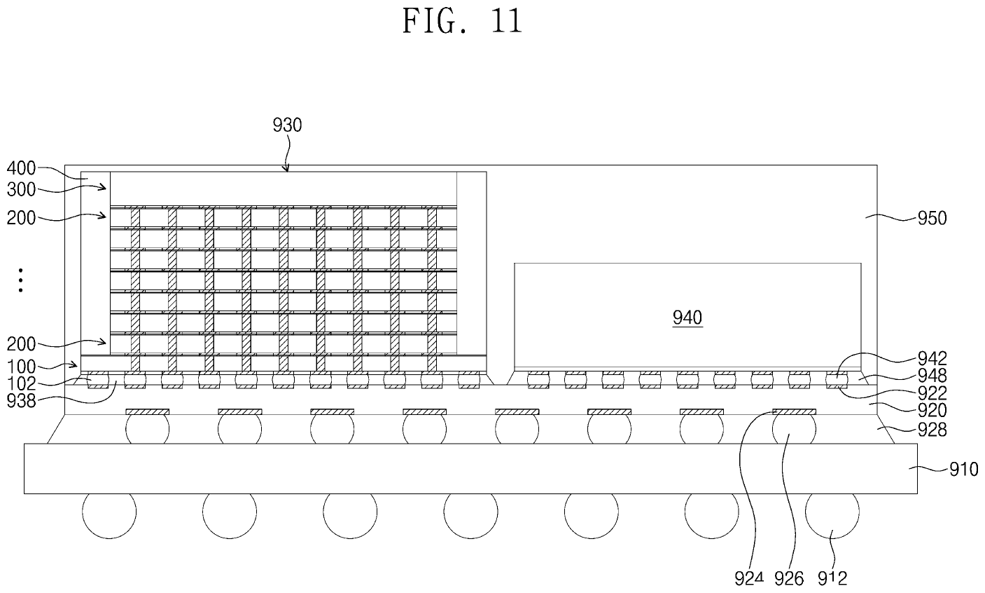

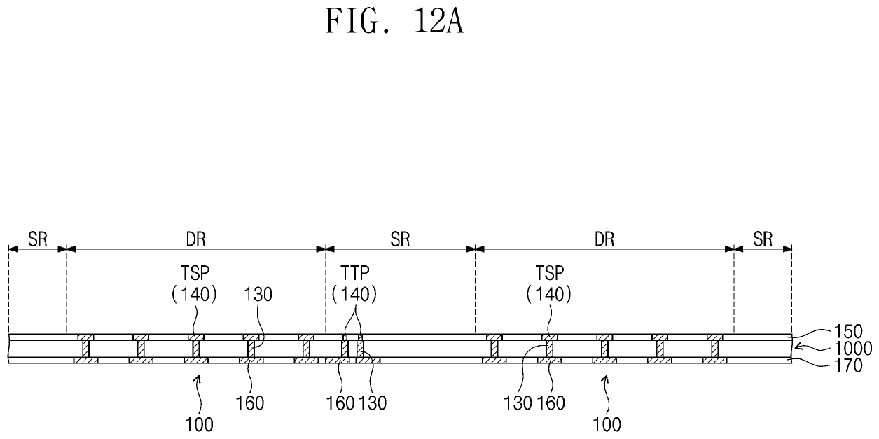

Alternatively, as illustrated in FIG. 9, in an embodiment the lower test pad BTP may have a octagonal ring shape when viewed in plan. In this embodiment, eight upper test pads TTP may be provided along the circumference of the octagonal ring shape of the lower test pad BTP. Each of the upper test pads TTP may be disposed adjacent to one of outer lateral surfaces of the lower test pad BTP. Each of the upper test pads TTP may partially overlap the lower test pad BTP (e.g., in a vertical direction).

Some examples of the lower test pad BTP are explained with reference to FIGS. 7 to 9. However, embodiments of the present inventive concept are not necessarily limited thereto. According to some embodiments, when viewed in plan, the lower test pad BTP may have a polygonal ring shape that has four or more outer lateral surfaces. In an embodiment, the upper test pads TTP may be provided in the same number as that of the outer lateral surfaces of the lower test pad BTP. Each of the upper test pads TTP may be disposed adjacent to one of the outer lateral surfaces of the lower test pad BTP. Each of the upper test pads TTP may partially overlap the lower test pad BTP. Alternatively, when viewed in plan, the lower test pad BTP may have a circular, polygonal, or any other closed curved shape.

FIG. 10 illustrates a cross-sectional view showing a semiconductor package according to some embodiments of the present inventive concept.

Referring to FIG. 10, a first semiconductor chip 100 may be provided. The first semiconductor chip 100 in an embodiment shown in FIG. 10 may be similar to the first semiconductor chip 100 discussed with reference to an embodiment shown in FIG. 1. In an embodiment, the first semiconductor chip 100 may be a logic chip. Alternatively, the first semiconductor chip 100 may be a memory chip or a semiconductor chip (e.g., a buffer chip) devoid of an electronic device, such as a transistor.

The first upper pads 140 of the first semiconductor chip 100 may further include upper connection pads TCP. The upper connection pads TCP may be disposed on the edge region ER. The upper connection pads TCP may be disposed to be spaced apart from the upper test pads TTP (e.g., in a vertical direction). The upper connection pads TCP may be electrically connected through the first vias 130 to the first lower pads 160.

A second semiconductor chip 200 may be provided. The second semiconductor chip 200 in an embodiment of FIG. 10 may be similar to the second semiconductor chip 200 discussed with reference to an embodiment of FIG. 1. The second semiconductor chip 200 may have a width (e.g., length in a direction parallel to an upper surface of the first semiconductor chip 100) less than a width of the first semiconductor chip 100 (e.g., length in a direction parallel to an upper surface of the first semiconductor chip 100). In an embodiment, the second semiconductor chip 200 may further include second vias 230, the second upper pads 240, and a second upper protection layer 250.

In an embodiment, the second lower pads 260 may further include lower connection pads BCP. The lower connection pads BCP may be disposed on the edge region ER. The lower connection pads BCP may be disposed to spaced apart from the lower test pads BTP (e.g., in a vertical direction). On an interface between the first semiconductor chip 100 and the second semiconductor chip 200, each of the lower connection pads BCP may be bonded to (e.g., directly bonded thereto) one of the upper connection pads TCP.

The second vias 230 may be provided to vertically penetrate the second semiconductor substrate 210 to come into connection with (e.g., direct connection therewith) a circuit layer of the second semiconductor chip 200. The second vias 230 may be patterns for vertical wiring. Some of the second vias 230 may be electrically connected to the upper signal pads TSP on the device region DR. Others of the second vias 230 may be electrically connected to the lower connection pads BCP on the edge region ER.

The second upper pads 240 may be disposed on the second semiconductor substrate 210. In an embodiment, the second upper pads 240 may include upper signal pads TSP and upper test pads TTP.

The upper signal pads TSP may be disposed on the device region DR. The upper signal pads TSP may be electrically connected through the second vias 230 to a circuit layer of the second semiconductor chip 200.

The upper test pads TTP may be disposed on the edge region ER. The upper test pads TTP may be electrically connected through the second vias 230 to the lower connection pads BCP. The upper test pads TTP may be electrically insulated from the circuit layer of the second semiconductor chip 200.

The second upper protection layer 250 may be disposed on (e.g., disposed directly thereon) the second semiconductor substrate 210. The second upper protection layer 250 may surround the second upper pads 240, such as lateral sides of the second upper pads 240. The second upper pads 240, such as an upper surface of the second upper pads 240 may be exposed by the second upper protection layer 250. For example, when viewed in plan, the second upper protection layer 250 may surround, but not contact, an upper surface of the second upper pads 240. The second upper protection layer 250 may have a top surface coplanar (e.g., in the vertical direction) with the top surface of the second upper pads 240.

In an embodiment, the semiconductor package may further include a third semiconductor chip 300 stacked on the second semiconductor chip 200. The third semiconductor chip 300 may have a structure substantially similar to that of the second semiconductor chip 200. For example, in an embodiment the third semiconductor chip 300 may include a third semiconductor substrate 310, a third circuit layer, third lower pads 360, and a third lower protection layer 370. In an embodiment, the third semiconductor chip 300 may not include a third via, a third upper pad, a third upper protection layer, and a third redistribution layer. However, embodiments of the present inventive concept are not necessarily limited thereto.

In an embodiment, the third circuit layer may include semiconductor devices formed on a bottom surface of the third semiconductor substrate 310, a device interlayer dielectric layer that buries the semiconductor devices, and a device wiring part in the device interlayer dielectric layer and connected to the semiconductor devices. The semiconductor devices may be disposed on the device region DR.

In an embodiment, the third lower pads 360 may be disposed below (e.g., directly below) the third semiconductor substrate 310, for example, below the third circuit layer. In an embodiment, the third lower pads 360 may include lower signal pads BSP and a lower test pad BTP. The lower signal pads BSP may be disposed on the device region DR. The lower signal pads BSP may be electrically connected to the semiconductor devices. The lower test pad BTP may be disposed on the edge region ER. The lower test pad BTP may be located at the same level (e.g., in the vertical direction) as that of the lower signal pads BSP. The lower test pad BTP may be electrically insulated from the semiconductor device.

The third lower protection layer 370 may be disposed below the third circuit layer. The third lower protection layer 370 may surround the third lower pads 360, such as lateral sides of the third lower pads 360. The third lower pads 360, such as an upper surface of the third lower pads 360, may be exposed by the third lower protection layer 370.

The third semiconductor chip 300 may be disposed on the second semiconductor chip 200. In an embodiment, the second upper pads 240 of the second semiconductor chip 200 may be vertically aligned with the third lower pads 360 of the third semiconductor chip 300. The second semiconductor chip 200 and the third semiconductor chip 300 may be in direct contact with each other.

The second semiconductor chip 200 may be connected to the third semiconductor chip 300. For example, the second and third semiconductor chips 200 and 300 may be in direct contact with each other. On an interface between the second semiconductor chip 200 and the third semiconductor chip 300, the second upper pads 240 of the second semiconductor chip 200 may be bonded to (e.g., directly bonded thereto) the third lower pads 360 of the third semiconductor chip 300. In an embodiment, the second upper pads 240 and the third lower pads 360 may constitute an intermetallic hybrid bonding.

As the second semiconductor chip 200 is bonded to the third semiconductor chip 300, on the edge region ER, the upper test pads TTP of the second semiconductor chip 200 may be electrically connected to the lower test pad BTP of the third semiconductor chip 300. In this embodiment, the upper test pads TTP of the second semiconductor chip 200 and the lower test pad BTP of the third semiconductor chip 300 may be combined to constitute a test structure.

The test structure including the upper test pads TTP of the second semiconductor chip 200 and the lower test pad BTP of the third semiconductor chip 300 shown in an embodiment of FIG. 10 may be substantially the same as the test structure TS including the upper test pads TTP of the first semiconductor chip 100 and the lower test pad BTP of the second semiconductor chip 200 discussed with reference to embodiments shown in FIGS. 1 to 9.

In an embodiment, the lower test pad BTP of the third semiconductor chip 300 may have a circular ring shape when viewed in plan. Each of the upper test pads TTP of the second semiconductor chip 200 may have a circular shape when viewed in plan. For example, each of the upper test pads TTP may have a cylindrical shape. The upper test pads TTP may be arranged along a circumference of the lower test pad BTP. Each of the upper test pads TTP may partially overlap the lower test pad BTP (e.g., in the vertical direction). In an embodiment, the same overlapping area size may be provided between the lower test pad BTP and each of the upper test pads TTP.

Each of the upper test pads TTP of the second semiconductor chip 200 may be connected to one of the first lower pads 160 through the second vias 230, the lower connection pads BCP, the upper connection pads TCP, and the first vias 130.

One of the first lower pads 160 may be electrically connected to one of the upper test pads TTP, and the first lower pads 160 may be electrically connected to other first lower pads 160 through the lower test pad BTP of the third semiconductor chip 300. In an embodiment, the first lower pads 160 electrically connected to the lower test pad BTP of the third semiconductor chip 300 may be pads for inputting signals in a process where bonding between the second semiconductor chip 200 and the third semiconductor chip 300 is tested.

A molding layer 400 may be disposed on (e.g., disposed directly thereon) the first semiconductor chip 100. In an embodiment, on a top surface of the first semiconductor chip 100, the molding layer 400 may surround the second semiconductor chip 200 and the third semiconductor chip 300. In an embodiment, the third semiconductor chip 300 may have a top surface exposed by a top surface of the molding layer 400. However, embodiments of the present inventive concept are not necessarily limited thereto, and the third semiconductor chip 300 may be buried in the molding layer 400 in some embodiments. The molding layer 400 may include a molding member, such as an epoxy molding compound (EMC).

FIG. 10 depicts that two semiconductor chips 200 and 300 are stacked on the first semiconductor chip 100. However, embodiments of the present inventive concept are not necessarily limited thereto. For example, according to some embodiments, three or more semiconductor chips may be stacked on the first semiconductor chip 100, and two adjacent ones of the semiconductor chips may be tested for whether their bonding is good by using the upper test pads TTP and the lower test pad BTP that are in direct contact with each other on an interface between the two adjacent semiconductor chips.

FIG. 11 illustrates a cross-sectional view showing a semiconductor module according to some embodiments of the present inventive concept.

Referring to FIG. 11, in an embodiment a semiconductor module may be, for example, a memory module including a module substrate 910, a chip stack package 930 and a graphic processing unit 940 that are mounted on the module substrate 910, and an outer molding layer 950 that covers the chip stack package 930 and the graphic processing unit 940. The semiconductor module may further include an interposer 920 provided on the module substrate 910.

The module substrate 910 may be provided. In an embodiment, the module substrate 910 may include a printed circuit board (PBC) having a signal pattern on a top surface thereof.

The module substrate 910 may be provided with module terminals 912 disposed thereunder (e.g., disposed directly thereunder). In an embodiment, the module terminals 912 may include a solder ball or a solder bump, and based on type and arrangement of the module terminals 912, the semiconductor module may be provided in the shape of one of a ball grid array (BGA) type, a fine ball-grid array (FBGA) type, and a land grid array (LGA) type.

The interposer 920 may be provided on the module substrate 910. In an embodiment, the interposer 920 may include first substrate pads 922 exposed on a top surface of the interposer 920 and second substrate pads 924 exposed on a bottom surface of the interposer 920. The interposer 920 may redistribute the chip stack package 930 and the graphic processing unit 940. In an embodiment, the interposer 920 may be flip-chip mounted on the module substrate 910. For example, the interposer 920 may be mounted on the module substrate 910 through substrate terminals 926 provided on (e.g., disposed directly thereon) the second substrate pads 924. In an embodiment, the substrate terminals 926 may include a solder ball or a solder bump. A first underfill layer 928 may be provided between the module substrate 910 and the interposer 920 (e.g., in the vertical direction).

The chip stack package 930 may be disposed on the interposer 920. The chip stack package 930 in an embodiment of FIG. 11 may have a structure that is the same as or similar to that of the semiconductor package discussed with reference to FIGS. 1 to 10. FIG. 11 depicts that a plurality of second semiconductor chips 200 are provided between the first semiconductor chip and the third semiconductor chip 300. However, embodiments of the present inventive concept are not necessarily limited thereto. According to some embodiments, one second semiconductor chip 200 is provided as shown in the embodiment of FIG. 10, or the chip stack package 930 include only two semiconductor chips such as the first semiconductor chip 100 and the second semiconductor chip 200 as shown in the embodiment of FIG. 1.

The chip stack package 930 may be mounted on the interposer 920. For example, the chip stack package 930 may be coupled through the external terminals 102 of the first semiconductor chip 100 to the first substrate pads 922 of the interposer 920. A second underfill layer 938 may be provided between the chip stack package 930 and the interposer 920 (e.g., in the vertical direction). The second underfill layer 938 may fill a space between the interposer 920 and the first semiconductor chip 100 and may surround the external terminals 102 of the first semiconductor chip 100.

In an embodiment, the graphic processing unit 940 may be disposed on the interposer 920. The graphic processing unit 940 may be disposed to be spaced apart from the chip stack package 930 (e.g., in a horizontal direction parallel to an upper surface of the module substrate 910). In an embodiment, the graphic processing unit 940 may have a thickness (e.g., length in the vertical direction) greater than thicknesses of the semiconductor chips 100, 200, and 300 of the chip stack package 930. The graphic processing unit 940 may include a logic circuit. For example, in an embodiment the graphic processing unit 940 may be a logic chip. The graphic processing unit 940 may be provided with bumps 942 on a bottom surface thereof. For example, the graphic processing unit 940 may be coupled through the bumps 942 to the first substrate pads 922 of the interposer 920. A third underfill layer 948 may be provided between the interposer 920 and the graphic processing unit 940 (e.g., in the vertical direction). The third underfill layer 948 may surround the bumps 942 while filling a space between the interposer 920 and the graphic processing unit 940.

The outer molding layer 950 may be provided on the interposer 920. The outer molding layer 950 may cover the top surface of the interposer 920. The outer molding layer 950 may encapsulate the chip stack package 930 and the graphic processing unit 940. In an embodiment, the outer molding layer 950 may have a top surface located at the same level or at a higher level than that of a top surface of the chip stack package 930. The outer molding layer 950 may include a dielectric material. For example, in an embodiment the outer molding layer 950 may include an epoxy molding compound (EMC).

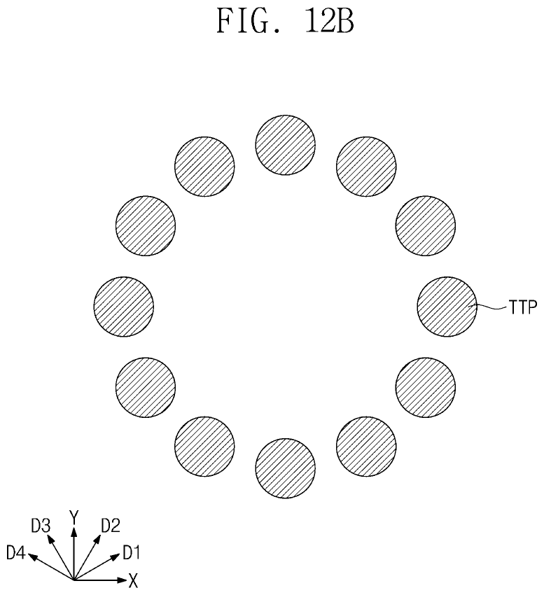

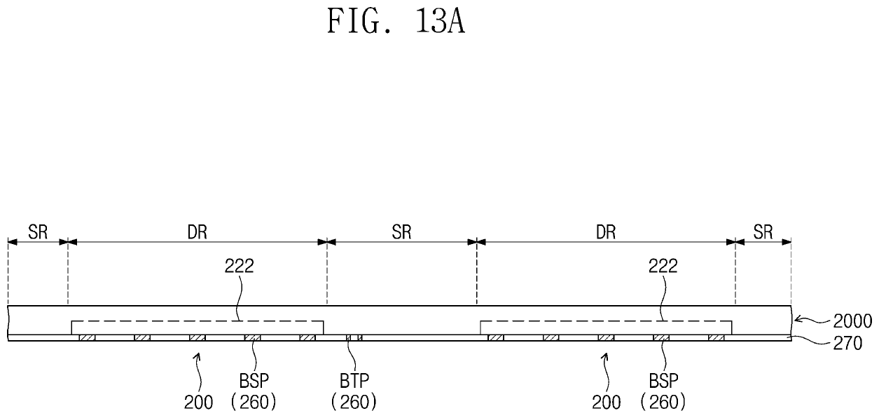

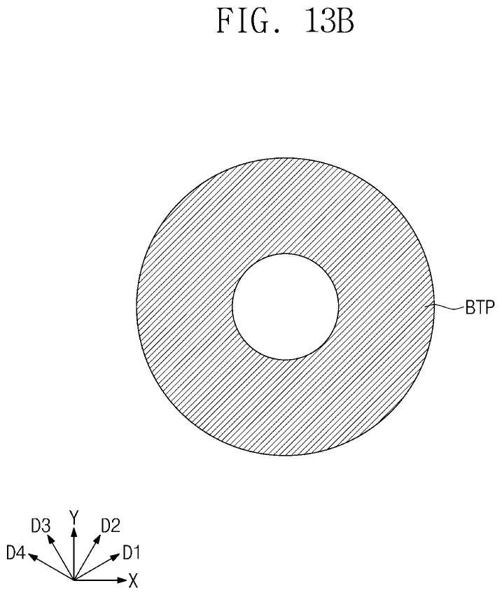

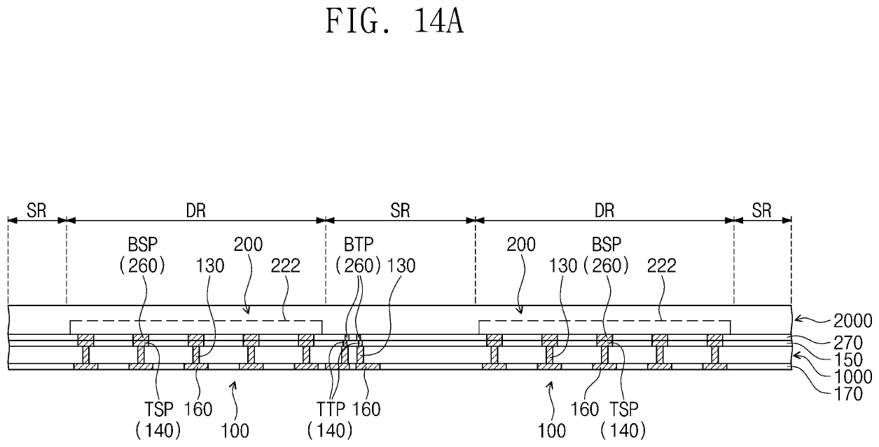

FIGS. 12A to 16A illustrate cross-sectional views showing a method of fabricating and testing a semiconductor package according to some embodiments of the present inventive concept. FIGS. 12B, 13B, 14B, 15B, 15C, 15D, 16B, and 16C illustrate plan views showing a test structure in a method of fabricating and testing a semiconductor package.

Referring to FIGS. 12A and 12B, a first semiconductor substrate 1000 may be provided. In an embodiment, the first semiconductor substrate 1000 may be a wafer formed of a semiconductor, such as silicon (Si). The first semiconductor substrate 1000 may include device regions DR and a scribe lane region SR positioned between the device regions DR (e.g., in a horizontal direction parallel to an upper surface of the first semiconductor substrate 1000). The first semiconductor substrate 1000 may include first semiconductor chips 100. Each of the first semiconductor chips 100 shown in an embodiment of FIG. 12A may have a structure that is the same as or similar to that of the first semiconductor chip 100 discussed with reference to FIGS. 1 to 10. The upper test pads TTP of the first semiconductor chips 100 may be positioned on the scribe lane region SR. In an embodiment, the upper test pads TTP may each have a circular shape when viewed in plan. The upper test pads TTP may have top surfaces having shapes are the same as each other. The upper test pads TTP may be arranged in a circular shape.

Referring to FIGS. 13A and 13B, a second semiconductor substrate 2000 may be provided. In an embodiment, the second semiconductor substrate 2000 may be a wafer formed of a semiconductor, such as silicon (Si). The second semiconductor substrate 2000 may include device regions DR that correspond to the device regions DR of the first semiconductor substrate 1000, and may also include a scribe lane region SR that corresponds to the scribe lane region SR of the first semiconductor substrate 1000. The second semiconductor substrate 2000 may include second semiconductor chips 200. Each of the second semiconductor chips 200 may have a structure that is the same as or similar to that of the second semiconductor chip 200 discussed with reference to FIGS. 1 to 10. The lower test pad BTP of each of the second semiconductor chips 200 may be positioned on the scribe lane region SR. In an embodiment, the lower test pad BTP may have a circular ring shape when viewed in plan.

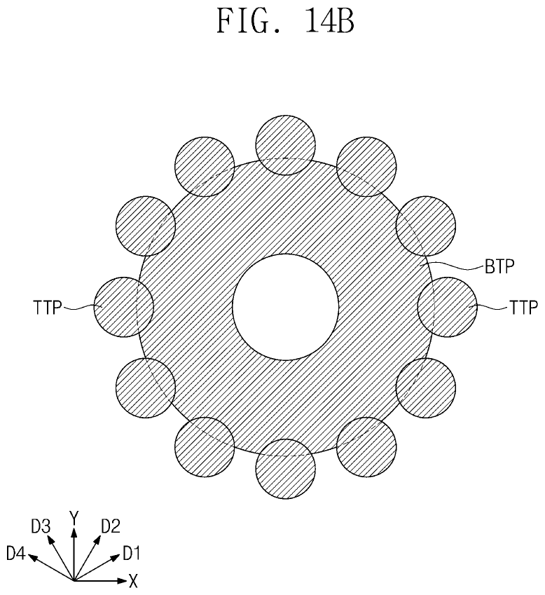

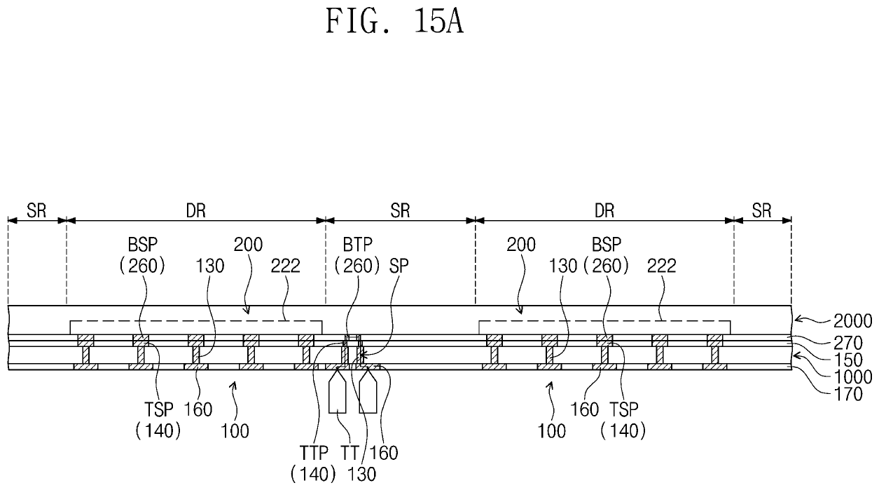

Referring to FIGS. 14A and 14B, the second semiconductor substrate 2000 may be mounted on the first semiconductor substrate 1000. The second semiconductor substrate 2000 may be aligned on the first semiconductor substrate 1000 to allow the first upper pads 140 of the first semiconductor substrate 1000 to reside on the second lower pads 260 of the second semiconductor substrate 2000. The second semiconductor substrate 2000 may be disposed on the first semiconductor substrate 1000 to allow the first upper pads 140 to directly contact the second lower pads 260. In an embodiment, an annealing process may then be performed on the first and second semiconductor substrates 1000 and 2000. The annealing process may bond (e.g., directly bond) the first upper pads 140 to the second lower pads 260. For example, in an embodiment the first upper pad 140 and the second lower pad 260 may be combined to form a single unitary piece. The first upper pads 140 and the second lower pads 260 may be automatically bonded to each other. For example, in an embodiment the first upper pads 140 and the second lower pads 260 may be formed of the same material (e.g., copper (Cu)), and may be bonded to each other by an intermetallic hybrid bonding process resulting from surface activation at an interface between the first upper pad 140 and the second lower pad 260 that are in direct contact with each other.

The bonding between the first upper pads 140 and the second lower pads 260 may bond (e.g., directly bond) the upper test pads TTP of the first semiconductor chip 100 and the lower test pad BTP of the second semiconductor chip 200 to each other. Each of the upper test pads TTP may partially overlap the lower test pad BTP. In an embodiment, when the first semiconductor substrate 1000 and the second semiconductor substrate 2000 are aligned with each other, an overlapping area size between the lower test pad BTP and each of the upper test pads TTP may be in a range of about 10% to about 30% of an area size of each of the upper test pads TTP. For example, in an embodiment the same overlapping area size may be provided between the lower test pad BTP and each of the upper test pads TTP.

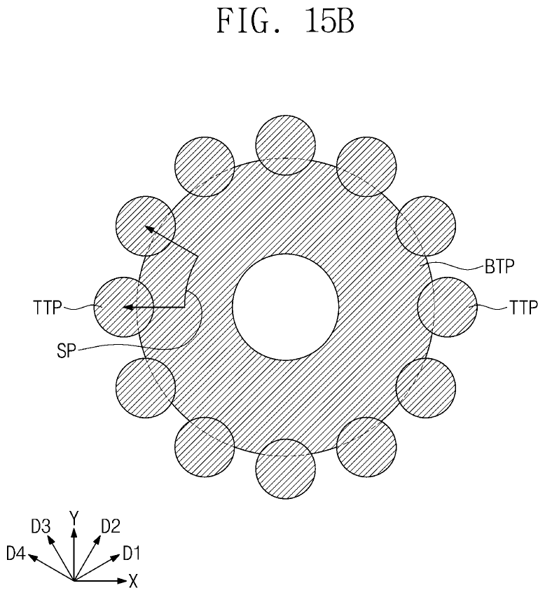

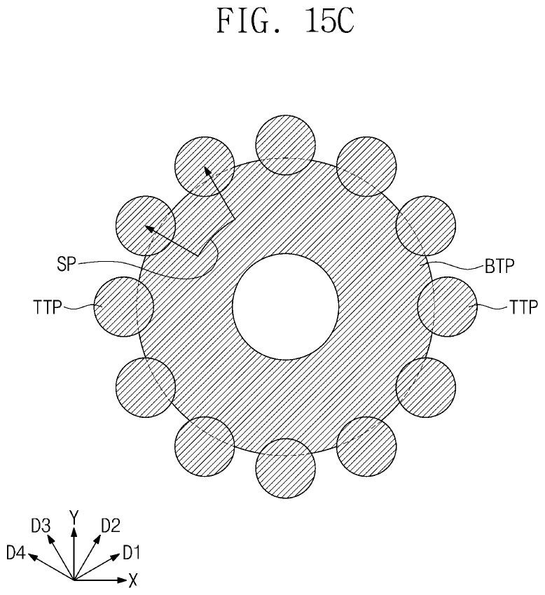

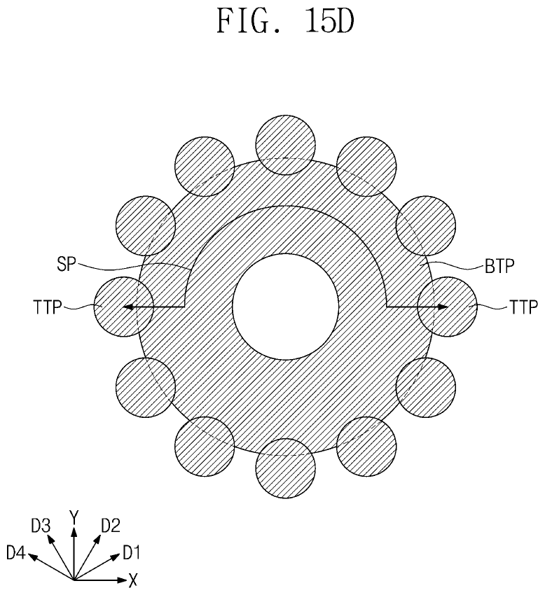

Referring to FIGS. 15A and 15B, a test process may be performed to test an alignment and bonding between the first semiconductor substrate 1000 and the second semiconductor substrate 2000. For example, an electrical resistance between two of the upper test pads TTP may be measured. In this embodiment, measurement tips TT may directly contact two of the first lower pads 160. The two first lower pads 160 may be the first lower pads 160 connected to the upper test pads TTP. A path SP of an electrical signal that is input or output through the measurement tips TT may be shown as indicated by an arrow in FIG. 15B. For example, the electrical signal path SP may be a transit path that passes through one of the first lower pads 160, one of the first vias 130, one of the upper test pads TTP, the lower test pad BTP, another of the upper test pads TTP, another of the first vias 130, and another of the first lower pads 160. As illustrated in FIG. 15B, the electrical signal path SP may pass through the upper test pad TTP positioned in a direction opposite to the first direction X, the lower test pad BTP, and the upper test pad TTP positioned in the sixth direction D4. The measurement tips TT may be used to measure an electrical resistance of the electrical signal path SP.

In an embodiment, the measurement tips TT may then directly contact another two of the first lower pads 160. As illustrated in FIG. 15C, a path SP of an electrical signal that is input or output through the measurement tips TT may pass through the upper test pad TTP positioned in the sixth direction D4, the lower test pad BTP, and the upper test pad TTP positioned in the fifth direction D3.

Alternatively, as illustrated in FIG. 15D, a path SP of an electrical signal that is input or output through the measurement tips TT may pass through the upper test pad TTP positioned in a direction opposite to the first direction X, the lower test pad BTP, and the upper test pad TTP positioned in the first direction X.

The measurement of electrical resistances by using the measurement tips TT may not be performed only on adjacent upper test pads TTP. The measurement of electrical resistances by using the measurement tips TT may be performed on two upper test pads TTP that are adjacent to each other or two upper test pads TTP that are not adjacent to each other.

In an embodiment, the measurement of electrical resistances by using the measurement tips TT may be performed at least twice or more. An overlapping area size between the lower test pad BTP and each of the upper test pads TTP (e.g., in a vertical direction) may be in a range of about 10% to about 30% of an area size of each of the upper test pads TTP. In an embodiment, then the first semiconductor substrate 1000 and the second semiconductor substrate 2000 are aligned with each other within this range, the same overlapping area size may be provided between the lower test pad BTP and each of the upper test pads TTP. Therefore, the same interfacial resistance may be present between the lower test pad BTP and each of the upper test pads TTP. In such a case, electrical resistances measured by the measurement tips TT may be the same as each other.

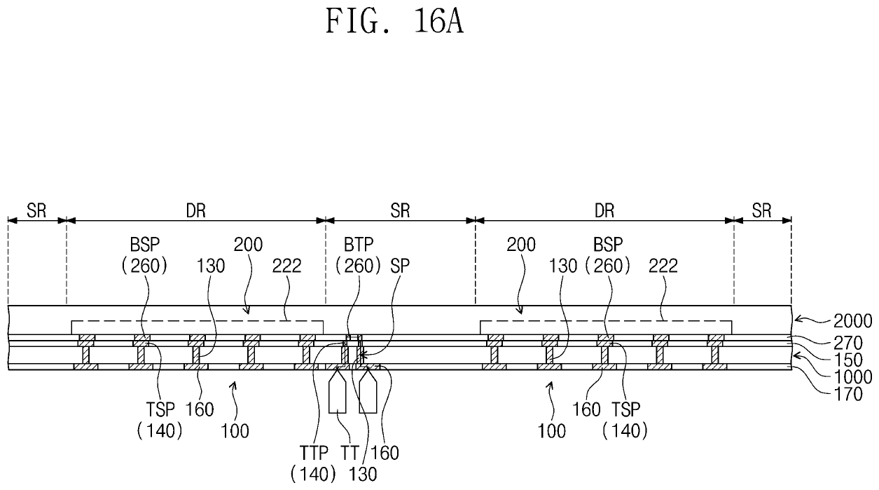

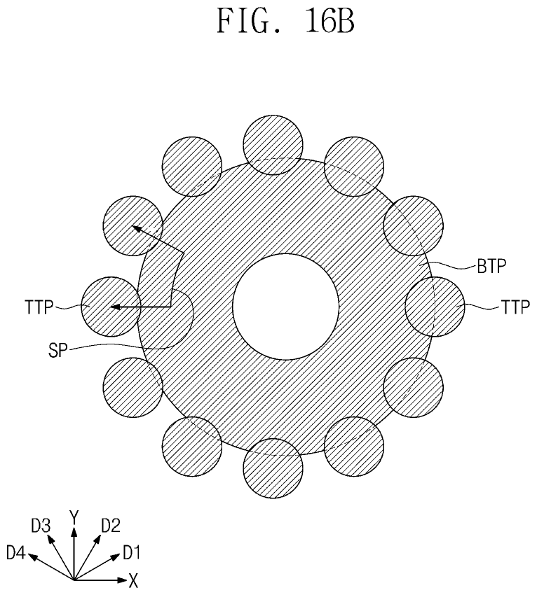

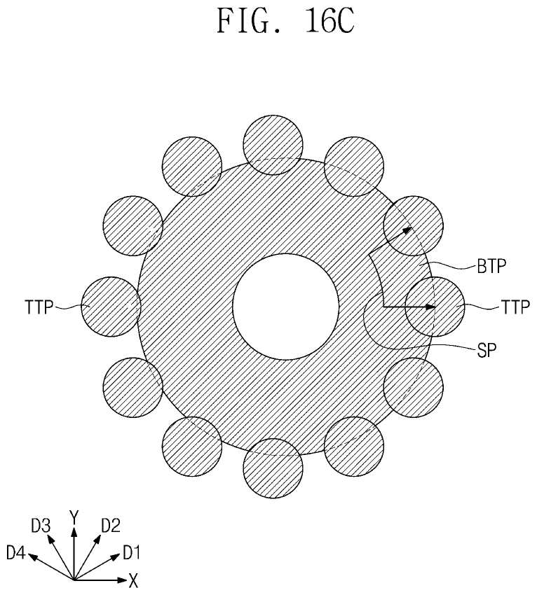

The first semiconductor substrate 1000 and the second semiconductor substrate 2000 may be misaligned with each other. FIGS. 16A to 16C depict an embodiment of misalignment between the first semiconductor substrate 1000 and the second semiconductor substrate 2000. FIGS. 16B and 16C depict by way of example a misalignment in which the second semiconductor substrate 2000 is shifted in the first direction X from the first semiconductor substrate 1000.

As illustrated in FIG. 16B, a path SP of an electrical signal that is input or output through the measurement tips TT may pass through the upper test pad TTP positioned in a direction opposite to the first direction X, the lower test pad BTP, and the upper test pad TTP positioned in the sixth direction D4. As the second semiconductor substrate 2000 is shifted in the first direction X from the first semiconductor substrate 1000, the closer to a direction opposite to the first direction X, the smaller the overlapping area size between the lower test pad BTP and each of the upper test pads TTP. Therefore, an electrical resistance measured by the measurement tips TT may be greater in this case than in a case where the first semiconductor substrate 1000 and the second semiconductor substrate 2000 are correctly aligned with each other. For example, when each of overlapping area sizes between the lower test pad BTP and the upper test pads TTP is less than about 10% of an area size of each of the upper test pads TTP, a large electrical resistance may be measured. A reduction in overlapping area size between the lower test pad BTP and each of the upper test pads TTP may cause an increase in measured electrical resistance.

In an embodiment, the electrical resistance between the upper test pads TTP measure by using the measurement tips TT may be compared with a reference resistance. The reference resistance may be an electrical resistance measured between the same upper test pads TTP when the first semiconductor substrate 1000 and the second semiconductor substrate 2000 are correctly aligned with each other as discussed with reference FIG. 16B. For example, the reference resistance may be the same as an electrical resistance of a test path measured when an overlapping area size between the lower test pad BTP and each of the upper test pads TTP is in a range of about 10% to about 30% of an area size of each of the upper test pads TTP. When the measured resistance is less than the reference resistance, the second semiconductor substrate 2000 may be misaligned with the first semiconductor substrate 1000. In this case, a direction in which the second semiconductor substrate 2000 is shifted from the first semiconductor substrate 1000 may be opposite to a direction in which the measured upper test pads TTP are positioned from a center of the lower test pad BTP.

Alternatively, the reference resistance may be a resistance measured between the upper test pads TTP other than the measured upper test pads TTP. As illustrated in FIG. 16C, a path SP of an electrical signal that is input or output through the measurement tips TT may pass through the upper test pad TTP positioned in the first direction X, the lower test pad BTP, and the upper test pad TTP positioned in the third direction D1. As the second semiconductor substrate 2000 is shifted in the first direction X from the first semiconductor substrate 1000, the closer to the first direction X, the larger the overlapping area size between the lower test pad BTP and each of the upper test pads TTP. Therefore, an electrical resistance measured by the measurement tips TT may be less in this case than in a case where the first semiconductor substrate 1000 and the second semiconductor substrate 2000 are correctly aligned with each other. For example, when each of overlapping area sizes between the lower test pad BTP and the upper test pads TTP is greater than about 10% of an area size of each of the upper test pads TTP, a small electrical resistance may be measured. An increase in overlapping area size between the lower test pad BTP and each of the upper test pads TTP may cause a reduction in measured electrical resistance.

Referring to FIGS. 16A to 16c, in an embodiment the measurement of electrical resistances by using the measurement tips TT may be performed at least twice or more. Electrical resistances may be measured between the upper test pads TTP. For example, it may be possible to measure electrical resistances between a plurality of electrical signal paths SP. In this case, the reference resistance may be one of the measured electrical resistances. For example, the measured electrical resistances may be compared with each other. When the measured resistances are different from each other, the second semiconductor substrate 2000 may be misaligned with the first semiconductor substrate 1000. A direction in which the second semiconductor substrate 2000 is shifted from the first semiconductor substrate 1000 may be a direction that is directed from the upper test pad TTP having the minimum measured electrical resistance towards the upper test pad TTP having the maximum measured electrical resistance. Alternatively, a direction in which the second semiconductor substrate 2000 is shifted from the first semiconductor substrate 1000 may be opposite to a direction in which the upper test pad TTP having the minimum measured electrical resistance is positioned from a center of the lower test pad BTP.

According to some embodiments of the present inventive concept, the test pads TTP and BTP in the first and second semiconductor substrates 1000 and 2000 may be used to test an alignment between the first semiconductor substrate 1000 and the second semiconductor substrate 2000. For example, the alignment between the first semiconductor substrate 1000 and the second semiconductor substrate 2000 may be tested by using a simplified process in which the external pads (e.g., the first lower pads 160) are used to measure an electrical resistance. Therefore, when testing the alignment between the first semiconductor substrate 1000 and the second semiconductor substrate 2000, it may be possible to avoid damage to the first semiconductor substrate 1000 and the second semiconductor substrate 2000. It may thus be possible to provide a method of testing a semiconductor package in which method a semiconductor package is free of damage caused by the test.

In addition, in accordance with the number and arrangement of the upper test pads TTP, it may be possible to measure the degree and direction of misalignment between the first semiconductor substrate 1000 and the second semiconductor substrate 2000. For example, it may be possible to provide a method of testing a semiconductor package that is capable of obtaining detailed information about the alignment between the first semiconductor substrate 1000 and the second semiconductor substrate 2000. Accordingly, the method of testing a semiconductor package may have a high test precision and may achieve good bonding between semiconductor substrates of a semiconductor package fabricated and tested thereby.

Additionally, a small number of the test structure TTP and BTP, for example, one test structure TTP and BTP may be used to test an alignment between the first semiconductor substrate 1000 on which a plurality of first semiconductor chips 100 are formed and the second semiconductor substrate 2000 on which a plurality of second semiconductor chips 200 are formed, and it may be unnecessary to test all of the alignments between the first semiconductor chips 100 and the second semiconductor chips 200. In conclusion, it may be possible to provide a simplified method of testing a semiconductor package.

Referring back to FIGS. 15A to 15D, to achieve an easy test of an alignment between the first semiconductor substrate 1000 and the second semiconductor substrate 2000, a size of area (referred to hereinafter as an overlapping area size) where each of the upper test pads TTP overlaps the lower test pad BTP may be in a range of about 10% to about 30% of an area size of each of the upper test pads TTP. In this description, the overlapping area size may be an area size measured when the first semiconductor substrate 1000 and the second semiconductor substrate 2000 are correctly aligned with each other. In a case where the overlapping area size is less than about 10% of the area size of each of the upper test pads TTP due to the first semiconductor substrate 1000 and the second semiconductor substrate 2000 being misaligned with each other, one or more of the upper test pads TTP may be completely spaced apart from the lower test pad BTP. For example, the one or more of the upper test pads TTP may be electrically insulated from the lower test pad BTP, and no electrical resistance may be measured between the test pads TTP and BTP. In a case where the overlapping area size is greater than about 30% of the area size of each of the upper test pads TTP, even when the overlapping area size is increased, an interfacial resistance between the lower test pad BTP and each of the upper test pads TTP may be constant without being increased. Therefore, even if the first semiconductor substrate 1000 and the second semiconductor substrate 2000 are misaligned with each other, the measured electrical resistances may be the same as each other when the overlapping area size between the lower test pad BTP and each of the upper test pads TTP is still greater than about 30% of the area size of each of the upper test pads TTP. Thus, no alignment test may be performed between the first semiconductor substrate 1000 and the second semiconductor substrate 2000.

Referring back to FIG. 1, in an embodiment a portion of the scribe lane region SR may be removed through a sawing process that uses a laser to separate semiconductor packages in which the first semiconductor chips 100 are bonded to the second semiconductor chips 200. For example, the laser may be irradiated along an arbitrary cutting line positioned in the scribe lane region SR, and the laser may remove the second semiconductor substrate 2000, the second lower protection layer 270, the first upper protection layer 150, the first semiconductor substrate 1000, and the first lower protection layer 170 that are provided on a portion of the scribe lane region SR. The cutting line may be set on the scribe lane region SR. The cutting line may extend in a direction that runs across between the device regions DR. The cutting line may be positioned at a middle of the scribe lane region SR. For example, distances between the cutting line and the device regions DR may be substantially identical or similar. In this case, the cutting line may be spaced apart from the test structure BTP and TTP. After the sawing process, a remaining region other than the removed portion of the scribe lane region SR may be defined as an edge region ER of a semiconductor package.

FIG. 1 depicts that the test structure BTP and TTP remains without being removed in the sawing process. However, embodiments of the present inventive concept are not necessarily limited thereto. According to some embodiments, a portion of the scribe lane region SR may be removed through a sawing process that uses a laser to separate semiconductor packages in which the first semiconductor chips 100 are bonded to the second semiconductor chips 200. The cutting line may be positioned at a middle of the scribe lane region SR. In this case, the test structure BTP and TTP may be positioned in a region that is removed through the sawing process. Thus, the test structure BTP and TTP may be removed in the sawing process, and may not remain in a semiconductor package.

Referring again to FIG. 1, external terminals 102 may be provided on (e.g., disposed directly thereon) the first lower pads 160.

In a method of testing a semiconductor package according to some embodiments of the present inventive concept, test pads in semiconductor substrates may be used to test an alignment between the semiconductor substrates. For example, the alignment between the semiconductor substrates may be tested by using a simplified process in which external pads are used to measure an electrical resistance. Thus, damage to the semiconductor substrates may be prevented when testing the alignment between the semiconductor substrates. It may thus be possible to provide a method of testing a semiconductor package in which method a semiconductor package is free of damage caused by the test.

In addition, in accordance with the number and arrangement of upper test pads, it may be possible to measure all of the degree and direction of misalignment between the semiconductor substrates. For example, it may be possible to provide a method of testing a semiconductor package which provides detailed information about the alignment or misalignment between the semiconductor substrates. Accordingly, the method of testing a semiconductor package may have high test precision and may achieve good bonding between the semiconductor substrates of a semiconductor package fabricated and tested thereby.

Moreover, a small number of test structure may be used to test the alignment between the semiconductor substrates, and it may be unnecessary to test all of the alignment between semiconductor chips. In conclusion, it may be possible to provide a simplified method of testing a semiconductor package.

Although the present inventive concept have been described in connection with the some embodiments of the present inventive concept illustrated in the accompanying drawings, it will be understood by one of ordinary skill in the art that variations in form and detail may be made therein without departing from the spirit and essential feature of the present inventive concept. Therefore, the described embodiments should thus be considered illustrative and not restrictive.

What is claimed is:

1. A semiconductor package, comprising:
a substrate;
a first semiconductor chip on the substrate, the first semiconductor chip including a first semiconductor substrate and a plurality of first test pads on a top surface of the first semiconductor substrate; and
a second semiconductor chip on the first semiconductor chip, the second semiconductor chip including a second semiconductor substrate and a second test pad on a bottom surface of the second semiconductor substrate,
wherein the first semiconductor chip and the second semiconductor chip are bonded to each other, the plurality of first test pads facing the second test pad,
wherein the second test pad has a circular ring shape when viewed in plan,
wherein the plurality of first test pads are arranged along a circumference of the second test pad, and
wherein areas that the plurality of first test pads overlap the second test pad have same sizes as each other.

2. The semiconductor package of claim 1, wherein each of the sizes of the areas that the plurality of first test pads overlap the second test pad is in a range of about 10% to about 30% of a size of each of the plurality of first test pads.

3. The semiconductor package of claim 1, wherein a number of the plurality of first test pads is in a range of 4 to 16.

4. The semiconductor package of claim 1, wherein each of the plurality of first test pads has a circular shape when viewed in plan.

5. The semiconductor package of claim 1, wherein the plurality of first test pads have a same size as each other.

6. The semiconductor package of claim 1, wherein, when viewed in plan, the plurality of first test pads are arranged at a same interval along the circumference of the second test pad.

7. The semiconductor package of claim 1, wherein:
the first semiconductor chip further includes a plurality of external pads on a bottom surface of the first semiconductor substrate,
wherein each of the external pads is electrically connected to one of the plurality of first test pads through wiring patterns in the first semiconductor substrate.

8. The semiconductor package of claim 1, wherein:
the first semiconductor chip further includes a first semiconductor device on a bottom surface of the first semiconductor substrate;
the second semiconductor chip further includes a second semiconductor device on the bottom surface of the second semiconductor substrate; and
the plurality of first test pads and the second test pad are electrically insulated from the first semiconductor device and the second semiconductor device.

9. The semiconductor package of claim 1, wherein:
the first semiconductor chip and the second semiconductor chip directly contact each other;
the plurality of first test pads and the second test pad constitute a single unitary piece formed of a same material;
a top surface of the first semiconductor chip is flat and coplanar with top surfaces of the plurality of first test pads; and
a bottom surface of the second semiconductor chip is flat and coplanar with a bottom surface of the second test pad.

10. The semiconductor package of claim 1, further comprising:
a third semiconductor chip on the second semiconductor chip;
wherein the second semiconductor chip further includes a plurality of third test pads on a top surface of the second semiconductor substrate,
wherein the third semiconductor chip includes a third semiconductor substrate and a fourth test pad on a bottom surface of the third semiconductor substrate,
wherein the second semiconductor chip and the third semiconductor chip are bonded to each other, the third test pads facing the fourth test pad,
wherein the fourth test pad has a circular ring shape when viewed in plan,
wherein, when viewed in plan, the third test pads are arranged along a circumference of the fourth test pad, and
wherein areas that the third test pads overlap the fourth test pad have same sizes as each other.

11. A semiconductor package, comprising:
a substrate;
a first semiconductor chip on the substrate; and
a second semiconductor chip on the first semiconductor chip,
wherein the first semiconductor chip includes:
a first semiconductor substrate;
a first circuit layer on a bottom surface of the first semiconductor substrate;
a plurality of first test pads on a top surface of the first semiconductor substrate;
a plurality of external pads on the bottom surface of the first semiconductor substrate; and
a plurality of through vias vertically penetrating the first semiconductor substrate to connect the plurality of first test pads to the external pads,
wherein the second semiconductor chip includes:
a second semiconductor substrate;
a second circuit layer on a bottom surface of the second semiconductor substrate; and
a second test pad on the bottom surface of the second semiconductor substrate,
wherein each of the plurality of first test pads partially overlaps the second test pad, and the plurality of first test pads are arranged at a same interval,
wherein the plurality of first test pads and the second test pad are electrically insulated from the first circuit layer and the second circuit layer, and
wherein each of the external pads is electrically connected through the through via to one of the plurality of first test pads.

12. The semiconductor package of claim 11, wherein:
each of the plurality of first test pads has a circular shape when viewed in plan, and
the second test pad has a circular, tetragonal, or polygonal ring shape when viewed in plan.

13. The semiconductor package of claim 12, wherein, when viewed in plan, the plurality of first test pads are arranged along a circumference of the second test pad.

14. The semiconductor package of claim 11, wherein areas that the plurality of first test pads overlap the second test pad have same sizes as each other.

15. The semiconductor package of claim 14, wherein each of the sizes of the areas that the plurality of first test pads overlap the second test pad is in a range of about 10% to about 30% of a size of each of the plurality of first test pads.

16. The semiconductor package of claim 11, wherein the plurality of first test pads have a same size as each other.

17. A method of testing a semiconductor package, the method comprising:
forming a wiring pattern in a first semiconductor substrate and a plurality of first test pads on a top surface of the first semiconductor substrate, the plurality of first test pads are electrically connected to the wiring pattern, and each of the plurality of first test pads having a circular shape when viewed in plan;
forming a second test pattern on a bottom surface of the second semiconductor substrate, the second test pad having a circular ring shape when viewed in plan;
bonding the first semiconductor substrate and the second semiconductor substrate to each other, the plurality of first test pads facing the second pad after the bonding to each other, the plurality of first test pads are arranged along a circumference of the second test pad, and each of the plurality of first test pads partially overlaps the second test pad;
forming a plurality of external pads on a bottom surface of the first semiconductor substrate, each of the external pads are electrically connected through the wiring pattern to one of the plurality of first test pads;
using two of the external pads to measure an electrical resistance of a test path; and
comparing the electrical resistance of the test path with a reference resistance.

18. The method of claim 17, wherein the test path includes a first first test pad of the plurality of first test pads, the second test pad, and a second first test pad of the plurality of first test pads, the first first test pad of the plurality of first pads, the second test, and the second first test pad of the plurality of first test pads are electrically connected in series.

19. The method of claim 17, wherein the reference resistance is equal to an electrical resistance of the test path measured when an overlapping area size between each of the plurality of first test pads and the second test pad is in a range of about 10% to about 30% of a size of each of the plurality of first test pads.

20. The method of claim 17, wherein:
each of the first semiconductor substrate and the second semiconductor substrate includes a plurality of device regions that are spaced apart from each other and a scribe lane region between the plurality of device regions,
the first semiconductor substrate further includes a plurality of first semiconductor devices correspondingly formed on the plurality of device regions, the plurality of first test pads are formed on the scribe lane region,
the second semiconductor substrate further includes a plurality of second semiconductor devices correspondingly formed on the plurality of device regions, the second test pad is formed on the scribe lane region, and
performing a cutting process on the scribe lane region after the comparing of the electrical resistance of the test path with the reference resistance.
